(19) United States
(12) Patent Application Publication
(10) Pub. No.: US 2026/0282987 A1
(43) Pub. Date: Sep. 17, 2026

(54) DIE BONDING SYSTEM INCLUDING ALIGNMENT AND BONDING ACTUATORS AND A METHOD OF USING THE SAME

(71) Applicant: CANON KABUSHIKI KAISHA, Tokyo (JP)

(72) Inventors: Nilabh K. ROY, Cedar Park, TX (US); Anshuman CHERALA, Austin, TX (US); Ozkan OZTURK, Round Rock, TX (US); Mario Johannes MEISSL, Austin, TX (US); Byung-Jin CHOI, Austin, TX (US)

(21) Appl. No.: 19/077,892

(22) Filed: Mar. 12, 2025

(51) Int. Cl. H01L 23/00

(52) U.S. Cl. CPC H10W 72/011; H10W 99/00; H10W 72/071; H10W 80/163; H10W 80/312; H10W 80/327

(57) ABSTRACT

A die bonding system can include a frame, a movable platform adapted to retain a die chuck, a set of bonding actuators operably coupled to the frame and the movable platform, and a set of alignment actuators operably coupled to the frame and the movable platform. In an implementation, each bonding actuator is adapted to apply a bonding force to the movable platform in a first direction parallel to a central axis, and each alignment actuator is adapted to apply an alignment force to the movable platform along an alignment force plane that is orthogonal to the central axis. In another implementation, the system further incudes a set of bonding flexures and a set of alignment flexures. Each of the flexures is coupled to its corresponding actuator and the movable platform. The die bonding system can achieve an adjustment cycle frequency of at least 50 Hz.

### FIELD OF THE DISCLOSURE

The present disclosure relates to a die bonding system including alignment and bonding actuators and a method of using the same.

### RELATED ART

Hybrid bonding allows a smaller die to be bonded to a bonding substrate having a plurality of dies. As dimensions decrease, proper placement and high equipment throughput make hybrid bonding a challenging operations. A die bonding head is designed to move in a die bonding direction so that a die can be bonded to a die bonding site of a bonding substrate. The die bonding direction may be in a Z-direction.

A high-precision placement tool designed to move in a Z-direction may be able to achieve an X-direction linear travel range of +/−4500 microns, a Y-direction linear travel range of +/−4500 microns, a Z-direction linear travel range of −3000 microns to 2100 microns. The Z-direction linear travel range may be the same as or less than the X-direction linear travel range and the Y-direction travel range. The high-precision placement tool can achieve an angular travel range for rotation about an axis in the X-direction (θ_{X}) is +/−68 milliradians (mrads), an angular travel range for rotation about an axis in the Y-direction (θ_{Y}) is +/−59 mrad, and an angular travel range for rotation about an axis in the Z-direction (θ_{Z}) is +/−127 mrad.

Such high-precision placement tools are not well suited for hybrid bonding where accurate reproducibility of die bonding and high throughput are desired in a manufacturing environment. A need exists to achieve high equipment throughput while still providing die placement accuracy and reproducibility in hybrid bonding.

### SUMMARY

In an aspect, a die bonding system can include a frame; a movable platform adapted to retain a die chuck; a set of bonding actuators operably coupled to the frame and the movable platform; and a set of alignment actuators operably coupled to the frame and the movable platform. Each bonding actuator can be adapted to apply a bonding force to the movable platform in a first direction parallel to and offset from a central axis passing through a center of the movable platform, and each alignment actuator can be adapted to apply an alignment force to the movable platform along an alignment force plane that is orthogonal to the central axis.

In an implementation, the set of bonding actuators is adapted to adjust a position in the first direction, tip, and tilt of the movable platform relative to the frame, and the set of bonding actuators are adapted to supply a peak bonding force to the movable platform.

In another implementation, the set of alignment actuators is adapted to adjust a position in a second direction, a position in a third direction, and a rotation about the central axis along a plane perpendicular to the central axis of the movable platform relative to the frame, and the second direction is orthogonal to the first direction, and the third direction is orthogonal to the first direction.

In still another implementation, the set of bonding actuators is adapted to apply the bonding forces to the movable platform that is at least two times the alignment forces adapted to be applied to the movable platform by the set of alignment actuators.

In a further implementation, a peak bonding force of each bonding actuator within the set of bonding actuators is at least 110 times a peak alignment force of each alignment actuator within the set of alignment actuators.

In another implementation, the die bonding system further includes the die chuck, wherein the movable platform includes a die chuck retention zone, and a location of the die chuck is adjustable within the die chuck retention zone.

In a particular implementation, while the die chuck is retained within the die chuck retention zone, a center of a die holding region of the die chuck is within a polygon, and vertexes of the polygon are at locations at which the set of bonding actuators apply the bonding forces to the movable platform.

In still another implementation, the die bonding system further includes the die chuck, wherein the die chuck is adapted to modulate a shape of a die during bonding. The set of bonding actuators is adapted to apply the bonding force sufficient to overcome modulation of the shape of the die such that the die complies with a die bonding surface of a substrate.

In a further implementation, when the movable platform is in a neutral state, each alignment actuator within the set of alignment actuators is adapted to move the movable platform along a plane perpendicular to the central axis, and the plane passes through a center of mass of the movable platform.

In another implementation, the set of bonding actuators has a first number of actuators, the set of alignment actuators has a second number of actuators, and the first number is different from the second number.

In another aspect, a die bonding system can include a frame; a movable platform adapted to retain a die chuck; a set of bonding actuators; a set of alignment actuators; and a set of alignment flexures. Each of the bonding flexures can have a corresponding bonding actuator, and each pair of a bonding flexure and its corresponding bonding actuator is operably coupled to the frame and the movable platform. Each of the alignment flexures can have a corresponding alignment actuator, and each pair of an alignment flexure and its corresponding alignment actuator can be operably coupled to the frame and the movable platform. The die bonding system can have an adjustment cycle frequency of at least 50 Hz, wherein the adjustment cycle frequency corresponds to a start time when a signal corresponding to a position of the movable platform is processed begins for a current adjustment cycle until an end time when adjusting the movable platform from a prior orientation to a new orientation is completed, wherein adjusting is performed in response to processing the signal during the current adjustment cycle.

In an implementation, the movable platform has a length in an X-direction, a width in a Y-direction, and a thickness in a Z-direction, wherein the length≥the width>the thickness. An X-direction linear travel range is at most +/−0.90% of the length of the movable platform, and a Y-direction linear travel range is at most +/−0.90% of the width of the movable platform.

In another implementation, the movable platform is adapted to achieve a position within an X-Y plane, the movable platform has a characteristic including a first rotation about a z-axis extending in a Z-direction through a center of mass of the movable platform, wherein the Z-direction is orthogonal to the X-Y plane, and an angular travel range of the first rotation is at most +/−50 mrad.

In a particular implementation, the movable platform has a length in an X-direction, a width in a Y-direction, and a thickness in the Z-direction, wherein the length≥the width>the thickness. The movable platform has further characteristics including a second rotation about an x-axis extending in the X-direction through the center of mass of the movable platform, and an angular travel range of the second rotation is +/−50 mrad, a third rotation about a y-axis extending in the Y-direction through the center of mass of the movable platform, an angular travel range of the third rotation is +/−50 mrad, and, in the Z-direction that is orthogonal to the X-Y plane, a Z-direction linear travel range is at most +/−2.5% of the length of the movable platform or at most +/−2.5% of the width of the movable platform.

In still another implementation, the adjustment cycle frequency is at least 200 Hz.

In a further implementation, each of the bonding actuators is adapted to provide a force of at least 20 N.

In a further aspect, a method can include coupling a first die to a first die chuck of a die bonding system. The die bonding system can include a first bonding head that includes a first frame, the first die chuck, a first movable platform that retains the first die chuck, a first set of first bonding actuators operably coupled to the first frame and the first movable platform, and a first set of first alignment actuators operably coupled to the first frame and the first movable platform. Each first bonding actuator can be adapted to apply a first bonding force to the first movable platform in a first direction parallel to and offset from a first central axis passing through a center of the first movable platform, and each first alignment actuator can be adapted to apply a first alignment force to the first movable platform along a first alignment force plane that is orthogonal to the first central axis.

The method can further include coupling a second die to a second die chuck of the die bonding system. The die bonding system can further include a second bonding head that is spaced apart from the first bonding head. The second bonding head can include a second frame, the second die chuck, a second movable platform that retains the die second chuck, a second set of second bonding actuators operably coupled to the second frame and the second movable platform, and a second set of second alignment actuators operably coupled to the second frame and the second movable platform. Each second bonding actuator can be adapted to apply a second bonding force to the second movable platform in a second direction parallel to and offset from a second central axis passing through a center of the second movable platform, and each second alignment actuator can be adapted to apply a second alignment force to the second movable platform along a second alignment force plane that is orthogonal to the second central axis passing.

The method can further include adjusting the first movable platform to a first adjusted orientation, wherein adjusting the first movable platform is performed using at least one actuator from any one or more actuators within the first set of first bonding actuators and the first set of first alignment actuators; adjusting the second movable platform to a second adjusted orientation, wherein adjusting the second movable platform is performed using at least one actuator from any one or more actuators within the second set of second bonding actuators and the second set of second alignment actuators; bonding the first die to a first die bonding site of a substrate, wherein bonding the first die includes activating the first set of first bonding actuators; and bonding the second die to a second die bonding site of the substrate, wherein bonding the second die includes activating the second set of second bonding actuators. The first die bonding site can be spaced apart from the second die bonding site, and bonding the first die and bonding the second die can be performed simultaneously during at least a same point in time.

In an implementation, the method further includes obtaining first signals from a first set of first position sensors, wherein the first signals correspond to a first prior orientation of the first movable platform, wherein adjusting the first movable platform is performed before adjusting the first movable platform to the first adjusted orientation; and obtaining second signals from a second set of second position sensors, wherein the second signals correspond to a second prior orientation of the second movable platform, wherein adjusting the second movable platform is performed before adjusting the second movable platform to the second adjusted orientation. A first cycle starts at a first point in time when processing the first signals begins and ends at a second point in time when adjusting the first movable platform is completed, a second cycle starts at a third point in time when processing the second signals begins and ends at a fourth point in time when adjusting the second movable platform is completed, and each of the first cycle and the second cycle corresponds to a frequency of at least 50 Hz.

In still another implementation, a surface of the substrate lies along an X-Y plane and includes the first die bonding site and the second die bonding site, each of the first die and the first die bonding site has a center, a maximum X-direction misalignment between the center of the first die and the center of the first die bonding site is at most 50 microns, and a maximum Y-direction misalignment between the center of the first die and the center of the first die bonding site is at most 50 microns.

In a further implementation, the first movable platform has a die chuck retention surface along an X-Y plane. After adjusting the first movable platform, the first movable platform has characteristics including a first rotation about a z-axis extending in a Z-direction through a center of mass of the first movable platform, wherein the Z-direction is orthogonal to the X-Y plane, a second rotation about an x-axis extending in a first X-direction through the center of mass of the first movable platform, and a third rotation about a y-axis extending in a Y-direction through the center of mass of the first movable platform. For each of the first rotation, the second rotation, and the third rotation, an angular travel range is at most +/−50 mrad.

### BRIEF DESCRIPTION OF THE DRAWINGS

Implementations are illustrated by way of example and are not limited in the accompanying figures.

FIG. 1 includes conceptual views of a die bonding system that can be used to bond dies to die bonding sites of a bonding substrate.

FIG. 2 includes an illustration of a side view illustrating a movable object, flexures, and forces that can be applied in a Z-direction to a movable object.

FIG. 3 includes an illustration of a top view illustrating the movable object in FIG. 2, flexures, and forces that can be applied in X-directions and Y-directions to the movable object.

FIG. 4 includes an illustration of a perspective view of a portion of a bonding head body.

FIG. 5A includes an illustration of a perspective view of the portion of the bonding head body in FIG. 4 after the portion of the bonding head body is turned upside down.

FIG. 5B includes an illustration of a perspective view of the portion of the bonding head body in FIG. 5A with the lower frame member removed and a die chuck along a bottom surface of the movable platform.

FIG. 6 includes an illustration of a perspective view of a portion of the bonding head body where the portion includes a lower frame, the movable platform, and bonding actuators coupled to the movable platform via flexures.

FIG. 7 includes an illustration of a top view of the movable platform and the bonding actuators in FIG. 6 and further includes alignment actuators.

FIG. 8 includes a process flow diagram for a method of bonding dies to bonding sites of the bonding substrate using the die bonding system of FIG. 1.

FIG. 9 includes a process flow diagram of a more detailed portion of the method in FIG. 8.

FIG. 10 includes an illustration of a side view of the die bonding system of FIG. 1 and further including a set of dies coupled to an array of die chucks and a bonding substrate coupled to a bonding substrate chuck.

FIG. 11 includes an illustration of a cross-sectional view of a die chuck and a die from the set of dies in FIG. 10 before a particular die is bowed.

FIG. 12 includes an illustration of a side view of the die bonding system of FIG. 10 after moving the set of dies over corresponding die bonding sites of the bonding substrate.

FIG. 13 includes an illustration of a cross-sectional view of a die chuck, and a die from the set of dies in FIG. 12 during a time when the die is bowed.

FIG. 14 includes an illustration of a cross-sectional view of a die chuck, and the particular and a bonding substrate when the particular die initially contacts a die bonding site of the bonding substrate.

FIG. 15 includes an illustration of a cross-sectional view of a die chuck, the particular die, and the bonding substrate of FIG. 14 when the die is bonded to the die bonding site of the bonding substrate.

FIG. 16 includes an illustration of a side view of the die bonding system, the set of dies, and the bonding substrate of FIG. 15 after the die chucks of the array of bonding heads are no longer coupled to the set of dies.

Skilled artisans appreciate that elements in the figures are illustrated for simplicity and clarity and have not necessarily been drawn to scale. For example, the dimensions of some of the elements in the figures can be exaggerated relative to other elements to help improve understanding of implementations of the inventive concepts.

### DETAILED DESCRIPTION

The following description in combination with the figures is provided to assist in understanding the teachings disclosed herein. The following discussion will focus on specific implementations of the teachings. This focus is provided to assist in describing the teachings and should not be interpreted as a limitation on the scope or applicability of the teachings.

Unless otherwise defined, all technical and scientific terms used herein have the same meaning as commonly understood by one of ordinary skill in the art to which this invention belongs. The materials, methods, and examples are illustrative only and not intended to be limiting. To the extent not described herein, many details regarding specific materials and processing acts are conventional and can be found in textbooks and other sources within the arts.

A die bonding system can be used to bond dies to a bonding substrate. The die bonding system can include a die bonding head and a die chuck coupled to the die bonding head. The die bonding head can include a frame, a movable platform adapted to retain the die chuck, a set of bonding actuators operably coupled to the frame and the movable platform, and a set of alignment actuators operably coupled to the frame and the movable platform. Each of the bonding actuators can be coupled to the frame via a corresponding bonding flexure, and each of the alignment actuators can be coupled to the frame via a corresponding alignment flexure. In an implementation, the set of bonding actuators can include at least three bonding actuators. For example, the set of bonding actuators can be three bonding actuators. In the same or different implementation, the set of alignment actuators can be at least three alignment actuators. The set of alignment actuators can be three or four alignment actuators. Thus, the number of bonding actuators may be the same as or different from the number of alignment actuators. The set of bonding actuators can be oriented such that the linear drive direction for the movable platform can be in a Z-direction, and the alignment actuators can move the movable platform in an X-Y plane that is orthogonal to the Z-direction.

The die bonding system can achieve high precision with respect bonding dies to the bonding substrate and achieve high production throughput. In an implementation, the die bonding system can achieve an X-direction linear travel range is at most +/−0.90% of the length of the movable platform, and a Y-direction linear travel range is at most +/−0.90% of the width of the movable platform. The same or different implementation, the die bonding system can have an X-direction linear travel range is at most +/−50 microns, at most +/−100 microns, or at most +/−200 microns, and a Y-direction linear travel range is at most +/−50 microns, at most +/−100 microns, or at most +/−200 microns. In either or both of the previous implementation or a different implementation, the movable platform has a characteristic including a first rotation about a z-axis extending in a Z-direction through a center of mass of the movable platform, and an angular travel range of the first rotation is at most +/−50 mrad, at most +/−20 mrad, at most +/−10 mrad, at most +/−6 mrad, or at most +/−3 mrad.

The die bonding system can achieve an adjustment cycle frequency of at least 50 Hz, at least 200 Hz, at least 500 Hz, or at least 1.1 kHz. In an implementation, the die bonding system 100 may be able to perform at an adjustment cycle frequency of at most 5 kHz. The adjustment cycle frequency corresponds to a start time when one or more signals corresponding to a position of a movable object, such as a movable platform, is processed begins for the current adjustment cycle until an end time when adjusting the movable objection, such as the movable platform, from a prior orientation to a new orientation is completed, wherein adjusting is performed in response to processing the signal during the current adjustment cycle. The die bonding system and method are understood better after reading this specification in conjunction with the figures.

Implementations described below are exemplary and do not limit the scope of the inventive concepts. While some die chucks will be described mostly with respect to an array of bonding heads, and other die chucks will be described mostly with respect to an array of die transfer seats, the die chucks for the array of bonding heads may be used for the array of die transfer seats, and the die chucks for the array of die transfer seats may be used for the array of bonding heads. Most of the description below addresses the array of die bonding heads. The concepts described herein may be applied to the array of die transfer seats.

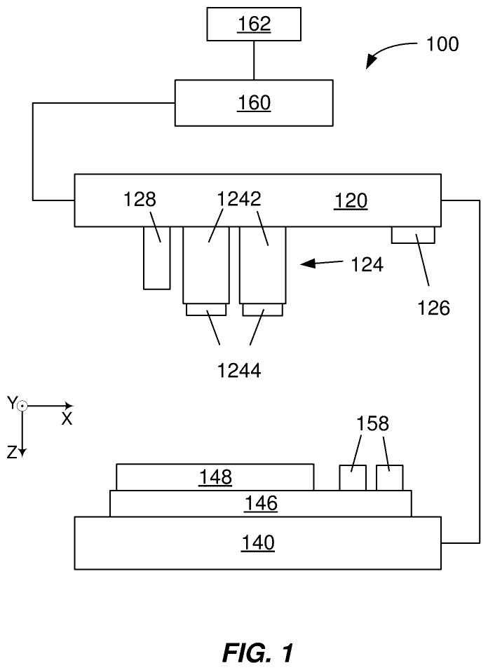

FIG. 1 includes a conceptual diagram of a die bonding system 100 that can be used to bond dies to die bonding sites of a bonding substrate coupled to a substrate chuck 148. The die bonding system 100 can be a single apparatus or more than one apparatus. In an implementation, the die bonding system 100 may include another apparatus or equipment not illustrated in FIG. 1.

FIG. 1 includes an equipment configuration of the die bonding system 100 and does not include the dies and the bonding substrate. The die bonding system 100 includes a bridge 120, a base 140, a controller 160 that is coupled to the bridge 120, the base 140, or one or more components coupled to the bridge 120 or the base 140, and a memory 162 coupled to the controller 160. The bridge 120 can be coupled to an array of bonding heads 124, a reference 126 having one or more alignment marks, and alignment hardware 128. The base 140 can be coupled to a bonding carriage 146. Although not illustrated, the die bonding system 100 may include die transfer seats (for example, pick-up heads, part of a pick-and-place tool, etc.) that can be used to transfer dies to the array of bonding heads 124 and may optionally further include a source chuck that can be used to hold a source substrate that includes dies to be bonded to a bonding substrate.

In FIG. 1 and other figures, the bridge 120, the base 140, and components physically between the bridge 120 or the base 140 can be organized along an X-direction, a Y-direction, a Z-direction, or a combination thereof. With respect to cross-sectional or side views, the X-direction is between the left-hand and right-hand sides of the drawings, the Z-direction is between the top and bottom of the drawings, and the Y-direction is into and out of the drawing sheet. Unless explicitly stated to the contrary, rotation occurs along an X-Y plane defined by the X-direction and Y-direction.

The array of bonding heads 124 can be arranged as a vector (a row or a column of bonding heads) or as a matrix (at least two rows and at least two columns of bonding heads). Regarding the matrix, the number of bonding heads within the array of bonding heads 124 may be different between rows, between columns, or between rows and columns. Some array configurations can include 3×1, 6×1, 2×2, 2×3, 2×4, 4×2 10×10, or another rectangular shape, where the first number corresponds to the number of bonding heads along a row or column, and the second number corresponds to the number of bonding heads along the other of the row or column. In theory, dies from an entire wafer may be transferred all at once. For such a configuration, from a bottom view, the array of bonding heads 124 may have fewer bonding heads along rows closer to the top and bottom of the array as compared to the row or the pair of rows closest to the center of the array, and the array of bonding heads 124 may have fewer bonding heads along columns closer to the left-hand side and right-hand side of the array as compared to the column or the pair of columns closest to the center of the array. After reading this specification, skilled artisans will be able to determine an arrangement for the array of bonding heads 124 that meets the needs or desires for a particular application.

Any or all of the bonding heads within the plurality of bonding heads 124 can include a bonding head body 1242. More details regarding the bonding head body 1242 are illustrated and described in more detail later in this specification. The bonding head body 1242 can be coupled to a die chuck 1244. The die chuck 1244 can be a vacuum chuck, a pin-type chuck, a groove-type chuck, an electrostatic chuck, an electromagnetic chuck, an edge gripping chuck, an ultrasonic chuck, or a Bernoulli chuck. The die chuck 1244 can be adapted to modulate the shape of a die during a die bonding sequence.

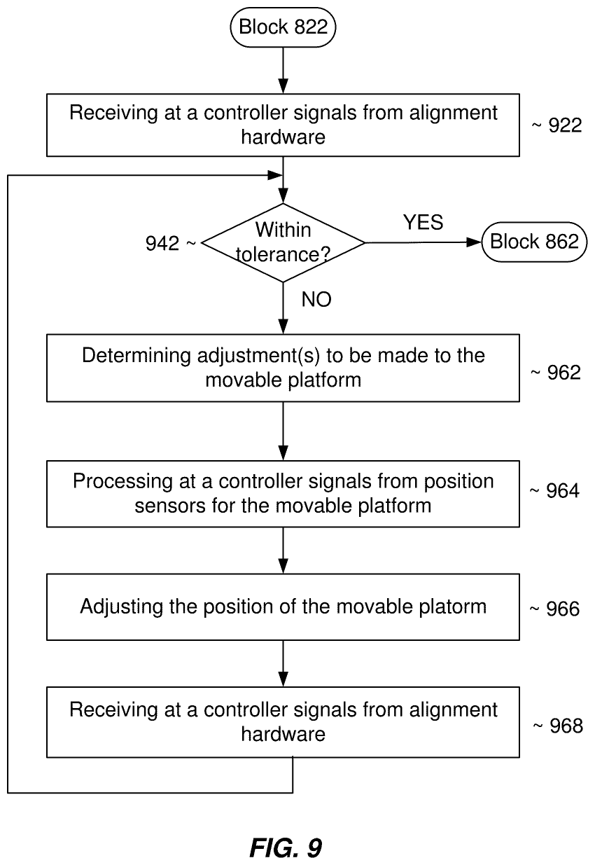

Alignment hardware 128 is coupled to the bridge 120. The alignment hardware 128 can include an optical component and provide information to the controller 160 or a local controller located within the alignment hardware 128, the bridge 120, the base 140 or a component coupled to the base, or a combination thereof. The information from the alignment hardware 128 can be used to determine a bonding pitch for the die bonding sites of a bonding substrate 1048 (illustrated in FIG. 9). Further, the information may be used to identify or confirm the bonding substrate 1048 is the correct substrate to which dies will be transferred and the position of bonding sites for those dies on the bonding substrate 1048.

Alignment hardware 158 is coupled to the bonding carriage 146. The alignment hardware 158 can include an optical component and provide information to the controller 160 or a local controller located within the alignment hardware 158, the bonding carriage 146, the base 140, or a combination thereof. The alignment hardware 158 can be used to align the bonding carriage 146 to the one or more alignment marks of the reference 126, align the bonding carriage 146 to the array of bonding heads 124, or both. The alignment hardware 158 can be to provide information used in adjusting positions of the die chucks 1244 within the array of bonding heads 124.

The die bonding system 100 can be controlled by the controller 160 in communication with the bridge 120, any component coupled to the bridge 120, the base 140, any component coupled to the base 140, or a combination thereof. The controller 160 can operate using a computer readable program, optionally stored in memory 162. The controller 160 can include a processor (for example, a central processing unit of a microprocessor or microcontroller), a field-programmable gate array (FPGA), an application specific integrated circuit (ASIC), or another electrical component adapted to carry out instructions in hardware, software, or firmware. The controller 160 can further include internal memory, such as a set of registers, a cache memory, a flash memory, or another memory. The controller 160 can be within the die bonding system 100. In another implementation (not illustrated) of the die bonding system 100, the controller 160 can be at least part of a computer external to the die bonding system 100, where such computer is bidirectionally coupled to the die bonding system 100. The controller 160 can include one processor or a plurality of processors that communicate over a bus, a local area intranet, or a wide area internet. In another implementation, the bridge 120, a component coupled to the bridge 120, the base 140, or a component coupled to the base 140 can include a local controller that provides some of the functionality that would otherwise be provided by the controller 160.

The memory 162 can include a non-transitory computer readable medium that includes instructions to carry out the actions associated with a hybrid bonding operation. The memory 162 can include a non-transitory computer readable medium that includes instructions to carry out the actions associated with a die bonding operation. The memory 162 can include a set of registers, a cache memory, a flash memory, a hard drive, or another memory. The memory 162 can further include data tables that can be accessed by the controller 160 to assist in determining an operating parameter, for example, positioning a movable platform in an X-Y plane, bonding a die to a bonding substrate within the die bonding system 100, or both as described below.

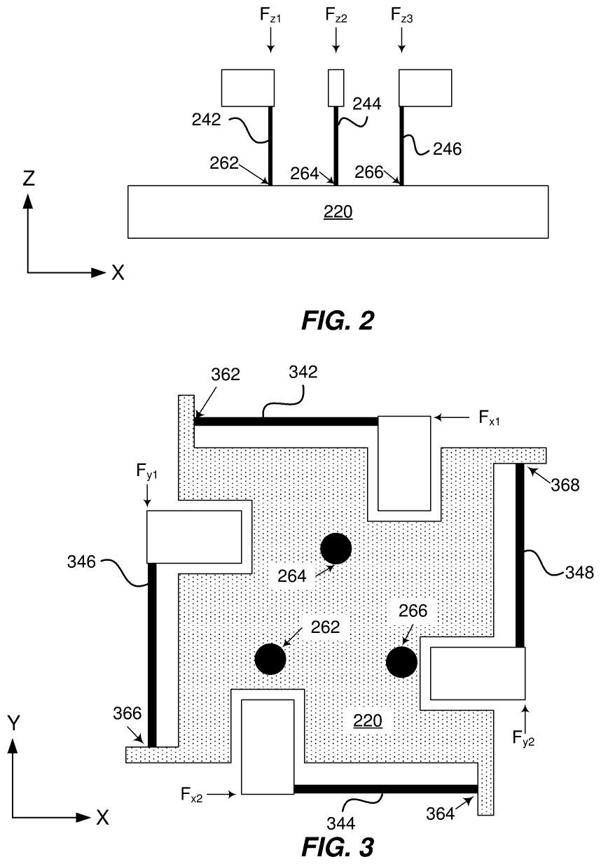

FIGS. 2 and 3 include side and top views of a movable object 220 and flexures 242, 244, 246, 342, 344, 346, and 348. In an implementation, flexures 242, 244, and 246 are a set of bonding flexures that can be coupled to corresponding bonding actuators described later in this specification. In the same or different implementation, flexures 342, 344, 346, and 348 are a set of alignment flexures that can be coupled to corresponding alignment actuators described later in this specification.

Forces can be applied and are illustrated in FIGS. 2 and 3 as F_{X1}, F_{X2}, F_{Y1}, F_{Y2}, F_{Z1}, F_{Z2}, and F_{Z3}. In an implementation, the forces can be applied by actuators (illustrated in subsequent figures). Each actuator can be a voice coil actuator, a piezoelectric actuator, a stepper motor, a servo motor, or a thermal expansion actuator.

When force is applied in a particular linear direction, for example, the Z-direction, its corresponding flexure can help to reduce undesired movement in any one or more other directions, for example the X-direction, Y-direction, θ_{Z} (rotation about an axis extending in the Z-direction (orthogonal to an X-Y plane) through a center of a movable object), θ_{X} (rotation about an axis extending in the X-direction through the center of the movable object, also referred to as tip), θ_{Y} (rotation about an axis extending in the Y-direction through the center of the movable object, also referred to as tilt), or any combination thereof. The flexure can include one or more flexures. For example, the flexure can include a wire flexure, a parallelogram-based flexure, a leaf hinge flexure, a notch hinge flexure, or a combination thereof. Each flexure has a center of stiffness. The center of stiffness is a specific point within the flexure in which applying a force applies a linear translation to a moving end of the flexure and reduces parasitic motions.

In FIG. 2, three forces in the Z-direction, F_{Z1}, F_{Z2}, and F_{Z3}, can be applied to distal ends of the flexures 242, 244, and 246. Proximal ends of the flexures 242, 244, and 246 can be coupled, and in a particular implementation, connected to the movable object 220 at locations 262, 264, and 266.

As used in this specification, a coupling can include a connection between two or more objects. However, not all couplings are connections. Two or more objects are coupled, and not connected, when movement of a first object does not result in the same movement at the same time in another object. As will be described later, one or more of the actuators can be coupled to the movable object 220 via the flexures 242, 244, 246, 342, 344, 346, and 348. Such actuator(s) may not be connected to the movable object 220 but may be coupled to each other. Thus, connections are a subset of couplings, and not all couplings are connections.

Regarding connections, two or more objects are connected if such two or more objects remain in a fixed position relative to each other and do not detectibly move with respect to each other. A connection may or may not have physical contact between two objects. For example, regarding no physical contact, the two objects may be spaced apart from and not physically contact each other because a washer or a gasket may lie between two objects. The two objects and the washer or gasket are parts of a physical connection because the two objects and the washer or the gasket remain in fixed position relative to one another. In another implementation, the washer or the gasket may not be present, and the two objects contact each other. Thus, connections between two objects may or may not have physical contact the two objects.

Referring to FIG. 3, two forces in the X-direction, F_{X1}, and F_{X2}, can be applied to distal ends of the flexures 342 and 344, and two forces in the Y-direction, F_{Y1}, and F_{Y2}, can be applied to distal ends of the flexures 346 and 348. Proximal ends of the flexures 342, 344, 346, and 348 can be connected to the movable object 220 at locations 362, 364, 366, and 368.

In an alternative implementation, the forces and flexure pairs along the X-Y plane may include three force and flexure pairs, rather than four pairs as illustrated in FIG. 3. The forces can be applied toward the centers, where the forces are offset by 120 degrees from one another (for example, at 4 o'clock, 8 o'clock and 12 o'clock directions).

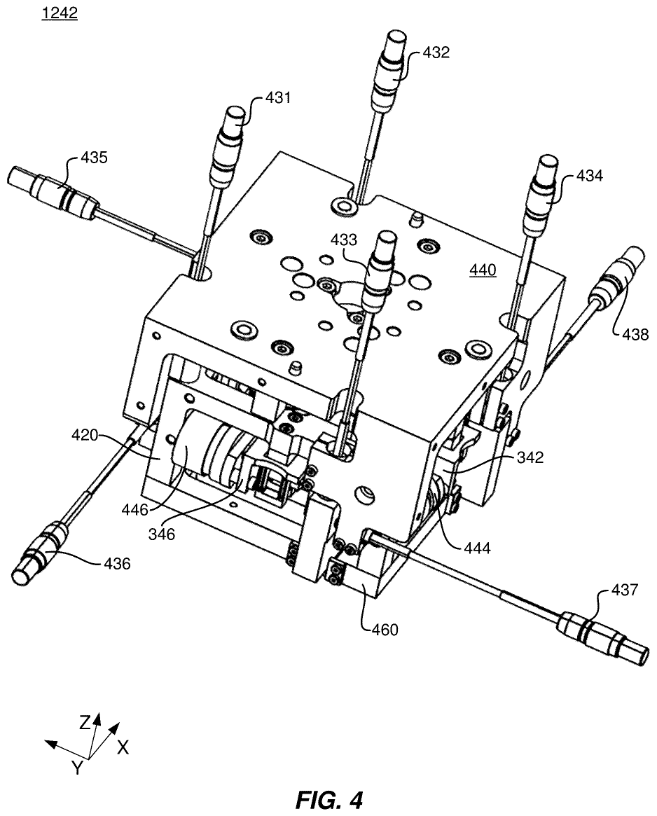

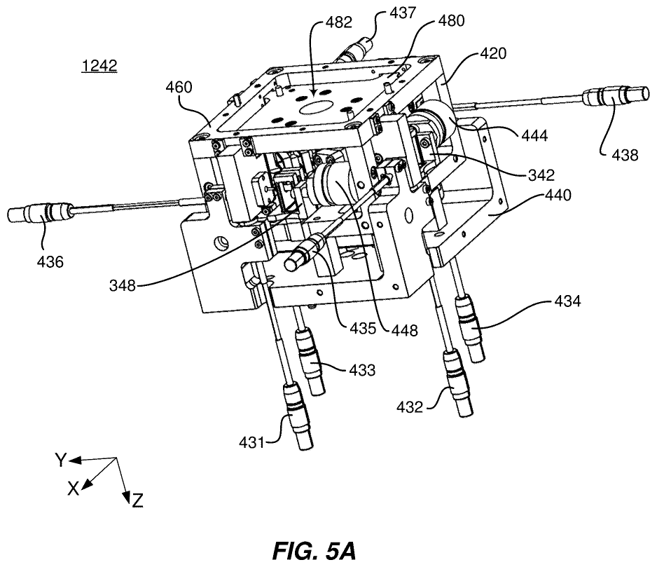

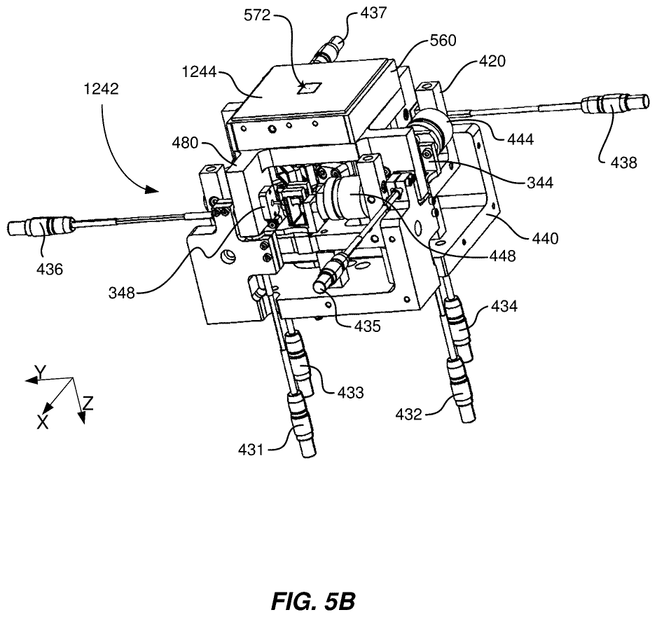

FIG. 4 includes a perspective view of a portion of a bonding head body 1242 when an upper frame member 440 is above a lower frame member 460, and FIG. 5A includes a perspective view of the portion of the bonding head body 1242 when the lower frame member 460 is above the upper frame member 440. In other words, FIG. 5A includes an illustration of the portion of the bonding head body 1242 in FIG. 4 after the portion is turned upside down. The bonding head body 1242 can include an internal frame member 420, the upper frame member 440, and the lower frame member 460. The internal frame member 420, the upper frame member 440, and the lower frame member 460 are coupled to each other. In an implementation, the internal frame member 420, the upper frame member 440, and the lower frame member 460 are connected together so that such frame members are in a fixed position relative to one another.

In the implementation as illustrated in FIGS. 4 and 5A, the movable object is a movable platform 480. The movable platform 480 is coupled to one or more of the frame members 420, 440, and 460 but is not connected to any of the frame members 420, 440, and 460. The movable platform 480 may be considered a floating object because it is not connected to any of the frame members 420, 440, and 460.

Referring to FIGS. 1, 5A, and 5B, the die chuck 1244 can be coupled to the bonding head body 1242, and in particular, to a bottom surface of the movable platform 480 via a die chuck retention plate 560. The die chuck 1244 includes a die holding region 572 that is configured to hold and modulate the shape of a die. In FIG. 5B, the die holding region 572 is centered in the middle of the die chuck 1244 but this is not a necessary feature. The die holding region 572 may instead be offset from the center of the die chuck 1244. This may be done to allow the pitch between neighboring bonding heads to be reduced. In FIG. 5B, the lower frame member 460 is not in to illustrate better the relationship between the die chuck 1244 and the movable platform 480. In the same or different implementation, the movable platform 480 can be adapted to retain the die chuck 1244 within a die chuck retention zone 482. The die chuck retention zone 482 can include at least a portion of an exposed surface along the bottom of the movable platform 480. A location of the die chuck 1244 can be adjustable within the die chuck retention zone 482. In an implementation, while the die chuck 1244 is retained within the die chuck retention zone 482, a center of a die holding region 572 of the die chuck 1244 is within a polygon, such as a triangle, rectangle, which may or may not be a square, a hexagon, an octagon, an irregular polygon, or another two-dimensional shape. Vertexes of the polygon are at locations at which the set of bonding actuators 462, 644, and 646 apply the bonding forces to the movable platform 480.

In an implementation, the movable platform 480 can have a length in an X-direction, a width in a Y-direction, and a thickness in a Z-direction, wherein the length≥the width>the thickness. In a non-limiting implementation, the movable platform 480 can have a length dimension of 125 mm and a Y-direction dimension of 125 mm. Many other sizes may be used.

Position sensors 431, 432, 433, 434, 435, 436, 437, and 438 can be used to determine the position of the movable platform 480. The position sensors 431, 432, 433, 434, 435, 436, 437, and 438 can be based on capacitance, induction, hall effect, magnetostrictive, optical interference, light received by the sensors,, or a proximity sensor. The positions sensors 431, 432, 433, 434, 435, 436, 437, and 438 can be of one or more types of position sensors including: capacitive sensors; inductive proximity sensors; hall effect sensor; magnetostrictive sensors; optical micrometer; spectral interference displacement sensors; confocal displacement sensors; interferometric displacement sensor. Each of the position sensors is a noncontact sensor that supplies a position of the moving body along one or more axes to the controller 160. In an implementation, the position sensors 431, 432, 433, 434, 435, 436, 437, and 438 may be connected to other portions of the bonding head body 1242 and pass through any one or more of the frame members 420, 440, and 460. In another implementation, the position sensors 431, 432, 433, 434, 435, 436, 437, and 438 may be connected to any one of the frame members 420, 440, and 460. In a further implementation, more or fewer position sensors may be present.

FIGS. 4, 5A, and 5B further comprise actuators 442, 444, 446, and 448 that can be any of the types of actuators previously described. The actuators 442, 444, 446, and 448 are a set of alignment actuators that can be operably coupled to the frame, such as the internal frame member 420, and the movable platform 480. The actuators 442, 444, 446, and 448 can be connected to the internal frame member 420. Each of the alignment actuators 442, 444, 446, and 448 can be adapted to apply an alignment force to the movable platform 480 along an alignment force plane that is orthogonal to a central axis passing through a center of the movable platform 480. In the same or different implementation, the actuators 442, 444, 446, and 448 can be used to move the movable platform 480 in the X-direction, Y-direction, and θ_{Z}.

In an implementation, when the movable platform 480 is in a neutral state (no net forces applied in each of the X-direction and the Y-direction), each alignment actuator within the alignment actuators 442, 444, 446, and 448 can be adapted to move the movable platform 480 along a plane perpendicular to the central axis that passes through the movable platform 480 in the Z-direction. The plane passes through a center of mass of the movable platform 480. Such a configuration may be useful to reduce the likelihood of unintended rotation in θ_{X} and θ_{Y} when an alignment actuator applies a force to the movable platform 480.

In any of the foregoing implementations or a further implementation, the actuators 442, 444, 446, and 448 are operably coupled and not connected to the movable platform 480. The actuator 442 can be operably coupled to the movable platform 480 via the flexure 342, the actuator 444 can be operably coupled to the movable platform 480 via the flexure 344, the actuator 446 can be operably coupled to the movable platform 480 via the flexure 346, and the actuator 448 can be operably coupled to the movable platform 480 via the flexure 348. Each pair of an alignment actuator and its corresponding alignment fixture is operably coupled, and, in a particular implementation, connected to the frame and the movable platform 480.

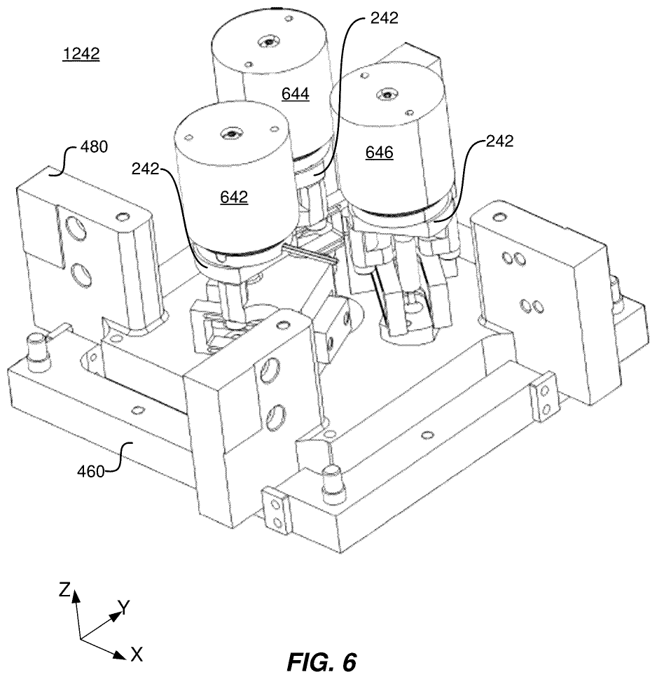

FIG. 6 includes a top perspective view of a portion of a bonding head body 1242 in FIGS. 4, 5A, and 5B. As compared to FIG. 4, the upper frame member 440, position sensors 431, 432, 433, 434, 435, 436, 437, and 438, the actuator-flexure pairs oriented along the X-Y plane (actuators 442, 444, 446, and 448, and flexures 342, 344, 346, and 348) are removed in FIG. 6 to illustrate the relationships between the movable platform 480 and the bonding actuator-flexure pairs along the bonding direction. Actuators 642, 644, and 646 are illustrated in FIG. 6.

The actuators 642, 644, and 646 are a set of bonding actuators that can be operably coupled to the frame, such as the upper frame member 440, and the movable platform 480. Each of the bonding actuators 642, 644, and 646 can be adapted to apply a bonding force to the movable platform in a Z-direction parallel to and offset from the central axis passing through the center of the movable platform 480. The set of bonding actuators 642, 644, and 646 can be adapted to adjust a position in the Z-direction, θ_{X}, and θ_{Y} of the movable platform 480 relative to the frame. Vertexes of the die chuck retention zone 482 can be locations at which the bonding actuators 642, 644, and 646 (illustrated in FIG. 6) apply bonding forces to the movable platform 480.

Any one or all of the bonding actuators 642, 644, and 646 can be adapted to apply a bonding force to the movable platform 480 that is different from the alignment force applied to the movable platform 480 by any one or more of the alignment actuators 442, 444, 446, and 448. The bonding actuators 642, 644, and 646 can be adapted to supply peak bonding forces to the movable platform 480. In an implementation, a peak bonding force of any one or more of the bonding actuators 642, 644, and 646 can be at least 110 times a peak alignment force of any one or more of the alignment actuators 442, 444, 446, and 448. The bonding actuators 642, 644, and 646 can be adapted to apply a bonding force sufficient to overcome modulation of the shape of a die such that the die complies with a die bonding surface of a bonding substrate. The bonding actuators 642, 644, and 646 together supply a bonding force and a force required to overcome the flexures. The bonding force is in a range from 20 N to 100 N. The force required to overcome the flexure stiffness in the bonding direction is in a range from 5 N to 10 N. Each of the alignment actuators 442, 444, 446, and 448 just need to overcome the flexure stiffness orthogonal to the bonding direction which is in a range from 1 N to 7 N per actuator. Each of the bonding actuators 642, 644, and 646 are designed to supply a peak force that is greater than a peak force supplied by each of the alignment actuators. In an implementation, each of the bonding actuators supply 2 to 100 times force than each of the alignment actuators.

In any of the foregoing implementations or a further implementation, the actuators 642, 644, and 646 are operably coupled and not connected to the movable platform 480. The actuator 642 can be operably coupled to the movable platform 480 via the flexure 242, the actuator 644 can be operably coupled to the movable platform 480 via the flexure 244, and the actuator 646 can be operably coupled to the movable platform 480 via the flexure 246. Each pair of a bonding actuator and its corresponding bonding fixture is operably coupled, and, in a particular implementation, connected to the frame and the movable platform 480. The actuators 442, 444, 446, 448, 642, 644, and 646 can be connected to the distal ends of the flexures 342, 344, 346, 348, 242, 244, and 246, respectively. Each of the actuators 442, 444, 446, 448, 642, 644, and 646 are adapted to apply a force through a center of stiffness of the flexure to which it is connected.

Electrical connections for the actuators 442, 444, 446, 448, 642, 644, and 646 are present but not illustrated in the figures to improve understanding of the positional relationships between the actuators 442, 444, 446, 448, 642, 644, and 646, the flexures 242, 244, 246, 342, 344, 346, and 348, and the movable platform 480.

Any one or more of the actuators 442, 444, 446, 448, 642, 644, and 646 can include a stationary portion and a moving portion. The stationary portion can be connected to any of the frame members 420, 440, and 460. In an implementation, the stationary portion of the alignment actuators 442, 444, 446, and 448 are connected to the internal frame member 420, and the stationary portion of the bonding actuators 642, 644, and 646 are connected to the upper frame member 440. In the same or another implementation, the moving portion of the actuator 442 can be connected to the distal end of the flexure 342, the moving portion of the actuator 444 can be connected to the distal end of the flexure 344, the moving portion of the actuator 446 can be connected to the distal end of the flexure 346, the moving portion of the actuator 448 can be connected to the distal end of the flexure 348, the moving portion of the actuator 642 can be connected to the distal end of the flexure 242, the moving portion of the actuator 644 can be connected to the distal end of the flexure 244, the moving portion of the actuator 646 can be connected to the distal end of the flexure 246. The proximal ends of the flexures 242, 244, 246, 342, 344, 346, and 348 are connected to the movable platform 480.

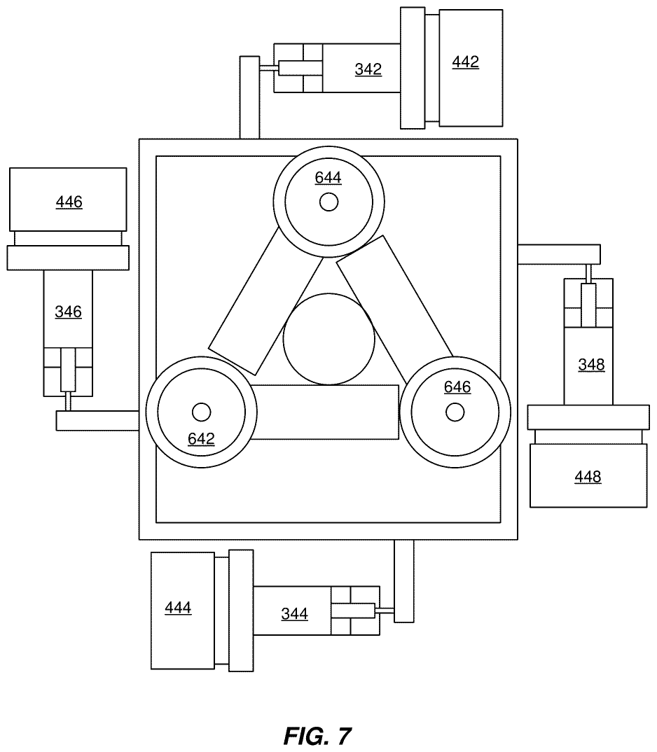

FIG. 7 includes a simplified top view for illustration of the movable platform 480, the actuators 442, 444, 446, 448, 642, 644, and 646, and the flexures 342, 344, 346, and 348. FIG. 7 can be a particular implementation of the portion of the die bonding system illustrated in FIG. 2. The flexures 242, 244, and 246 are present between the actuators 642, 644, and 646 and the movable platform 480, but the flexures 242, 244, and 246 are not seen from the top view illustrated in FIG. 7.

The die bonding system 100 as illustrated and described herein can achieve good performance needed for a high-precision hybrid bonding. Linear travel ranges expressed below are for a movable object in which the movable object can move linearly in a first direction, also referred to as the bonding direction. Second and third directions are perpendicular to the first direction and each other. In an implementation, the movable object can be the movable platform 480 of the die bonding system 100. The bonding direction can be the Z-direction, and the second and third directions can be the X-direction and the Y-direction. The movable platform 480 can be adapted to achieve a position within an X-Y plane.

The linear travel range of the movable platform 480 in the Z-direction is sufficient to allow a die held by the die chuck 1244 to be bonded to a die bonding site of a bonding substrate. In the X-direction and Y-direction, the movable platform 480 may not need to be moved as much. The linear travel range of the movable platform 480 in the die bonding direction, Z-direction in this example, is greater than the linear travel range to the two orthogonal directions, the X-direction and the Y-direction in this example. The linear travel range of the movable platform 480 in the Z-direction can be at least 1.1, at least 2.0, at least 3.0, or at least 5.0 times the linear travel range of the movable platform 480 in each of the X-direction and the Y-direction. In an implementation the linear travel range of the movable platform 480 in the Z-direction can be at most 40 times the linear travel range of the movable platform 480 in each of the X-direction and the Y-direction

The first direction linear travel range may be at most +/−2.5% of the length of the movable platform 480 or at most +/−2.5% of the width of the movable platform 480. In the same or different implementation, each of the second and third direction linear travel ranges may be at most +/−0.90%, at most +/−0.50%, or at most +/−0.25% of the length of the movable platform 480 or at most +/−0.90%, at most +/−0.50%, or at most +/−0.25% of the width of the movable platform 480.

Linear travel ranges can be expressed in terms of actual distances as compared to relative values. In an implementation, a first direction linear travel range can be at most +/−2000 microns, at most +/−500 microns, or at most +/−50 microns. In the same or different implementation, the second and third direction linear travel ranges can be at most +/−2000 microns, at most +/−50 microns, or +/−10 microns.

The first, second, and third directions described above can have corresponding angular travel ranges. Rotations about such directions can include θ_{DD}, θ_{Tip}, and θ_{Tilt}, where θ_{DD} is rotation about an axis in the drive direction, θ_{Tip} is rotation about an axis in the second direction, and θ_{Tilt} is the rotation about an axis in the third direction. In an implementation, an angular travel range for θ_{DD} may be at most +/−50 mrads, at most +/−3 mrad, or at most +/−0.1 mrad. In the same or different implementation, each of θ_{Tip}, and θ_{Tilt} may have an angular travel range at most +/−50 mrad, at most +/−1 mrad, or +/−0.1 mrad. Referring to FIGS. 2 to 7, the die bonding system 100 is configured such that the movable platform 480 is to move in the Z-direction. Thus, θ_{DD} can be θ_{Z}, θ_{Tip} can be θ_{X}, and θ_{Tilt} can be θ_{Y}. The inventor has found the repeatability for the bonding head is: an absolute value for the X-direction linear travel range is less than 10 nm; an absolute value for the Y-direction linear travel range is less than 10 nm; an absolute value for the Z-direction linear travel range is less than 30 nm; an absolute value for the θ_{DD}-direction angular travel range is less than 3 mrad; an absolute value for the θ_{Tip}-direction angular travel range is less than 3 mrad; and an absolute value for the θ_{Tilt}-direction angular travel range is less than 3 mrad.

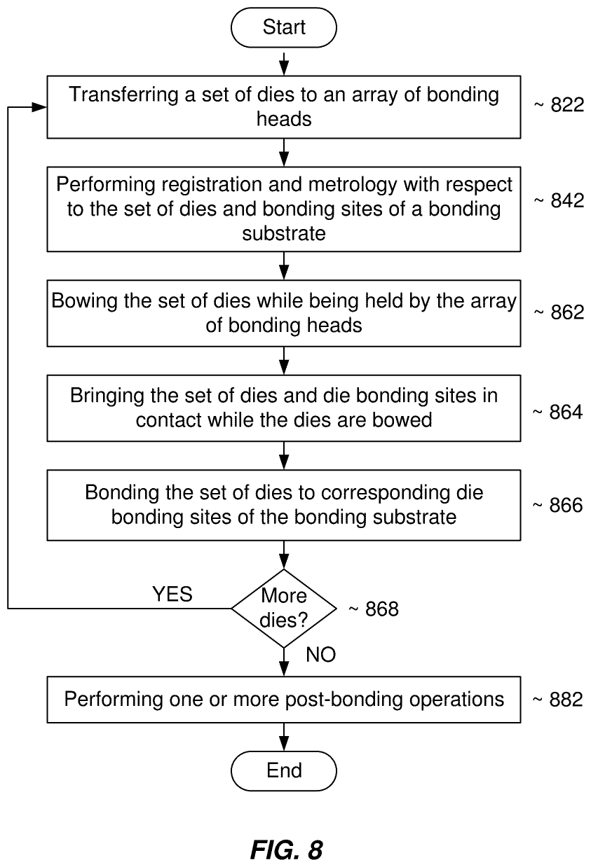

Attention is directed to methods of bonding dies to die bonding sites of a bonding substrate using the die bonding system 100 when transferring a set of dies to die bonding sites of a bonding substrate. The process flow for the method is illustrated in FIG. 8. FIG. 9 includes details for at least some of the actions that can occur when performing the operation in block 842 in FIG. 8.

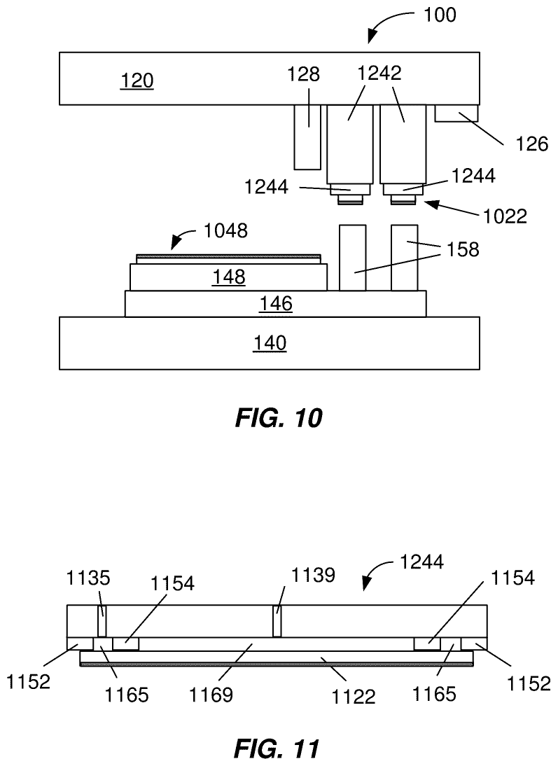

The method can include transferring the set of dies to an array of bonding heads at block 822 in FIG. 8. In FIG. 10, a die transfer carriage (not illustrated) and the bonding carriage 146 are moved to the right. The die transfer carriage is moved so that the array of bonding heads 124 is over the array of die transfer seats. If needed or desired, the alignment hardware 128, alignment hardware 158, or both can be used to confirm the array of die transfer seats (not illustrated) is properly positioned with respect to the array of bonding heads 124. The controller 160 or a local controller can transmit a signal for the die transfer seats within the array of die transfer seats to be extended toward the bonding heads within the array of bonding heads 124, for the bonding heads within the array of bonding heads 124 to be extended toward the die transfer seats within the array of die transfer seats, or both. A set of dies 1022 are retained by the die chucks 1244. A bonding substrate 1048 is coupled to the substrate chuck 148. The dark bands along the set of dies 1022 and the bonding substrate 1048 represent activated surfaces to assist in bonding the set of dies 1022 to the bonding substrate 1048. In a non-limiting implementation, the activated surfaces can be hydrolyzed surfaces of a silicon oxide material.

FIG. 10 includes the set of dies 1022 after being transferred from the array of die transfer seats to the array of bonding heads 124. FIG. 11 includes a particular die 1122 within the set of dies 1022 that is held by the bonding head 124. Referring to FIGS. 1, 10, and 11, the controller 160 or a local controller can transmit a signal for a pressure actuator for a bonding head within the array of bonding head 124 to activate the pressure actuator to evacuate a flow channel 1135 and a zone 1165 between lands 1152 and 1154. The vacuum within the zone 1165 can be sufficient to hold a particular die 1122 that is a die within the set of dies 1022. A flow channel 1139 and the zone 1169 can be at or near ambient pressure or be evacuated similar to the flow channel 1135 and the zone 1165. The controller 160 or local controller may or may not transmit a signal to activate a pressure actuator for the flow channel 1139 to achieve the desired pressure (vacuum or at or near ambient pressure).

The method can further include performing registration, alignment, and metrology with respect to the set of dies and bonding sites of a bonding substrate at block 842 in FIG. 8. FIG. 9 includes at least a portion of actions performed in block 842. A further action may or may not be performed in addition to the actions listed in FIG. 9. Thus, (1) one or more actions may occur after block 822 in FIG. 8 and before block 922, (2) one or more actions may occur along the YES branch diamond 942 and before block 862 in FIG. 8, or both (1) and (2).

Referring to FIG. 9, the method can include receiving at a controller signals from alignment hardware at block 922. The alignment hardware 128 can obtain information regarding the bonding substrate 1048, and the alignment hardware 158 can obtain information regarding the set of dies 1022.

The controller 160 or a local controller can receive signals from the alignment hardware 128 regarding information on the bonding substrate 1048. The signals can include information that may or may not correspond to part number(s) for the bonding substrate 1048. Such information can be used to confirm that the correct bonding substrate 1048 is coupled to the substrate chuck 148. If the information includes the part number, the controller 160 or local controller can obtain from the memory 162 or another memory further information regarding the bonding substrate 1048, such as locations of bonding pads for the bonding substrate 1048, sizes of bonding pads for the bonding substrate 1048, topography of the bonding substrate 1048 where the set of dies 1022 will be bonded to the substrate 1048, or other information related to the surface of the bonding substrate 1048. Such information can be based on the design of the bonding substrate 1048. Thus, the areal dimensions or locations can represent design values, and not actual values, for the parameters. The design information is not required for all implementations, and thus, obtaining the design information may or may not be performed.

Alternatively, or in addition to the design values, the information for actual values for locations of bonding pads for the bonding substrate 1048, sizes of bonding pads for the bonding substrate 1048, topography of the bonding substrate 1048 or where the set of dies 1022 will be bonded to the substrate 1048 can be determined by the controller 160 or a local controller based at least in part on signals transmitted by the alignment hardware 128 and received by the controller 160 or a local controller.

The controller 160 or a local controller can receive signals from the alignment hardware 158 regarding information the set of dies 1022. The signals can include information that may or may not correspond to part number(s) for the set of dies 1022. Such information can be used to confirm that the correct dies will be bonded to the bonding substrate 1048. If the information includes part number(s), the controller 160 or local controller can obtain from the memory 162 or another memory further information regarding the set of dies 1022, such as areal dimensions of dies within the dies 1022, locations of bonding pads within the dies for the set of dies 1022, or sizes of bonding pads for the set of dies 1022, or other information related to the surfaces of the dies within the set of dies 1022. Such information may be based on the designs of the set of dies 1022. Thus, information related to the set of dies 1022 can represent design values, and not actual values, for the parameters. The design information may or may not assist in more quickly performing the registration or metrology. The design information is not required for all implementations, and thus, obtaining the design information may or may not be performed.

Alternatively, or in addition to the design values, the information for actual values for areal dimensions of the dies 1022, locations of bonding pads within the dies for the set of dies 1022, or sizes of bonding pads for the set of dies 1022, or other information related to the surface of the dies within the set of dies 1022 can be determined by the controller 160 or a local controller based at least in part on signals transmitted by the alignment hardware 158 and received by the controller 160 or a local controller. In an implementation, the alignment information of the dies is collected with the dies at the plane coincident with the bonding plane to reduce any unobservable alignment errors induced due to the Z-motion of the bonding head. In an implementation, the alignment information of the dies is collected when the dies are at the bonding plane while the substrate chuck 148 is not opposite the array of bonding heads.

The controller 160 or a local controller can use the information generated from the signals from the alignment hardware 128 and 158 to determine whether the relative positions of the die bonding sites within the bonding substrate 1048 and the set of dies 1022 are within tolerance at decision diamond 942 in FIG. 9. The positions can include any one or more of an X-direction difference, a Y-direction difference, a Z-direction difference, a θ_{X} difference, a θ_{Y} difference, and θ_{Z} difference. If all of the differences are equal to or less than the tolerances, the process can proceed along the YES branch from the decision diamond 942. The tolerance is selected based on the size and pitch of the bonding pads that are to bonded. In an implementation, the tolerance can be at most 100 nm, at most 50 nm, at most 20 nm, at most 10 nm, at most 5 nm, at most 2 nm, or at most 1 nm depending on the die being bonded.

If any one or more of the differences is/are greater than its/their corresponding tolerance(s), the process proceeds along the NO branch from the decision diamond 942. The method can include determining adjustment(s) to be made to the movable platform at block 962. The position sensors 431, 432, 433, 434, 435, 436, 437, and 438 can provide information regarding the position of the movable platform 480 before the adjustment is made. Thus, the method can include processing, at a controller, signals from positions sensors for the movable platform movable at block 964. The controller 160 or a local controller can receive signals from the position sensors 431, 432, 433, 434, 435, 436, 437, and 438. If information regarding the position was previously received from the position sensors 431, 432, 433, 434, 435, 436, 437, and 438, obtaining the information at this time can be omitted. The controller 160 or a local controller can process the information received from the position sensors 431, 432, 433, 434, 435, 436, 437, and 438 to determine the current position of the movable platform 480.

The method can further include adjusting the position of the movable platform at block 966. The controller 160 or a local controller can send one or more signals to any one or more of the actuators 442, 444, 446, 448, 642, 644, and 646 that can move the platform 480.

The actuators 442, 444, 446, and 448 can affect motion in the X-direction, Y-direction, and θ_{Z}. Movement in the X-direction, Y-direction, and θ_{Z} can affect the relative positions of the bonding pads of the set of dies 1022 and the bonding pads of the bonding substrate 1048 within the previously described linear travel ranges for the X-direction and Y-direction and angular travel range for θ_{Z}. The adjustments made for such movements can help achieve good electrical and physical contact and acceptably low contact resistance as compared to not making any adjustment.

The actuators 642, 644, and 646 can affect motion in the Z-direction, θ_{X}, and θ_{Y}. Ideally, as illustrated in FIGS. 10 and 11, the bonding surfaces of the set of dies 1022 and bonding surfaces within the bonding substrate 1048 are perfectly parallel to each other. In practice, the bonding surfaces of the set of dies 1022 and bonding surfaces within the bonding substrate 1048 may or may not be perfectly parallel to each other. Movement in the Z-direction, θ_{X}, and θ_{Y} can affect the relative positions of bonding surfaces of the set of dies 1022 and the bonding surfaces of the bonding substrate 1048 are within tolerances for the Z-direction, θ_{X}, and θ_{Y}. The adjustments made for such movements can help reduce the likelihood of causing damage to any die of the set of dies 1022, any bonding site within the bonding substrate 1048, or a combination of any die any die of the set of dies 1022 and the bonding sites within the bonding substrate 1048 due to nonuniform contact when a force is being applied during bonding of any one or more dies within the set of dies 1022, any one or more bonding sites within the bonding substrate 1048, or both any one or more dies within the set of dies 1022, any one or more bonding sites within the bonding substrate 1048.

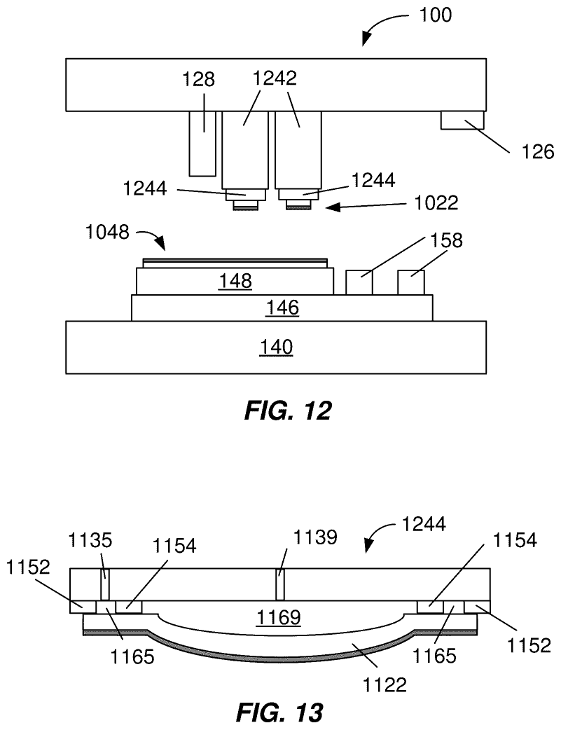

The method can include receiving at a controller signals from alignment hardware at block 968 in FIG. 9. In an implementation, after the adjustment was made to the movable platform 480, the alignment hardware 158 can obtain information regarding the set of dies 1022. In same or different implementation, the alignment hardware 128 can obtain information regarding the bonding substrate 1048. The method continues as it returns to decision diamond 942 to determine if all of the dimensional differences are within tolerance. When the dimensional differences between the set of dies 1022 and the bonding substrate 1048 are within tolerance, the set of dies 1022, the bonding substrate 1048, or both are moved such that the set of dies 1022 overlap their corresponding die bonding sites within the bonding substrate 1048 as illustrated in FIG. 12. The process continues at block 862 in FIG. 8.

The method can further include bowing the set of dies while being held by the array of bonding heads at block 862 in FIG. 8. Data can be useful in determining how much pressurization should be used to bow the set of dies 1022. For example, as a die occupies a larger area (X-direction and Y-direction dimensions) and is thinner (Z-direction dimension), less pressure is needed to bow the die as compared to a die that occupies a smaller area, is thicker, or both. If the die is attached to a backing plate, the combined thickness of the die and backing plate can be used when determining the pressure to achieve a desired amount of bowing. The data can be obtained for many different die areas and thicknesses. The memory 162 or a table or database external to the die bonding system 100 can have data that correlates different areas and thicknesses of the die and the positive pressures or ranges of positive pressures to use to allow for sufficient bowing of the dies.

Referring to FIGS. 1 and 13, the controller 160 or a local controller can transmit a signal for a pressure actuator to be activated and allow a pressurized gas to increase the pressure within a flow channel 1139 and a zone 1169. A pressure sensor can sense the pressure within the flow channel 1139 and transmit signals to the controller 160 or the local controller, so that the controller 160 or the local controller can control the pressure to be at or within acceptable tolerance of a target pressure. As the pressure within the zone 1169 increases, the particular die 1122 bows away die chuck 1244 and toward the base 140 or the bonding substrate 1048 that is coupled to the base 140 (illustrated in FIG. 12). FIG. 13 illustrates the particular die 1122, and the other dies within the set of dies 1022 can have a bowed shape similar to the particular die 1122 illustrated in FIG. 13.

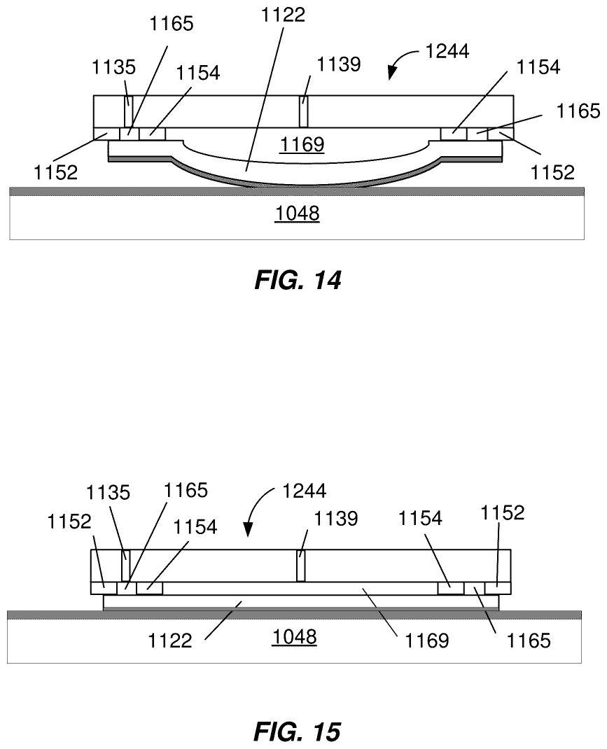

The method can include bringing the set of dies and die bonding sites in contact while the dies are bowed at block 864 in FIG. 8. Referring to FIGS. 1 and 14, the array of die chucks 1244 within the array of bonding heads 124 can be extended toward the bonding substrate 1048, the substrate chuck 148 can be extended toward the array of bonding heads 124, or both. As illustrated in FIG. 14, the center of the particular die 1122 contacts a die bonding site of the bonding substrate 1048 before other portions of the particular die 1122 contact the die bonding site. Thus, the likelihood of trapped air between the particular die 1122 and bonding substrate 1048 during bonding is substantially less than if bowing was not performed.

The method can further include bonding the set of dies to corresponding die bonding sites of the bonding substrate at block 866 in FIG. 8. Referring to FIGS. 1 and 15, the die chucks 1244 within the array of bonding heads 124 can be further extended toward the bonding substrate 1048, the substrate chuck 148 can be extended toward the array of bonding heads 124, or both. The amount of bowing can be reduced as contact area between the particular die 1122 and the corresponding die bonding site of the bonding substrate 1048 increases.

Pressure is exerted to bond the set of dies 1022 to corresponding bonding sites of the bonding substrate 1048. In an implementation, the bonds can be oxide-to-oxide bonds. The force during bonding can be at least 5 N, at least 10 N, at least 20 N, at least 50 N or at least 100 N. In an implementation, regarding pressure, the pressure during bonding can be in a range from 0.5 N/cm² to 20 N/cm². The controller 160 or a local controller can transmit a signal for a motor, hydraulic pressure system, or another mechanical component that can be used to drive the array of bonding heads 124, the substrate chuck 148, or both in the Z-direction to achieve the bonding pressure. During bonding, if needed or desired, the pressure within the zone 1169 can be at a positive pressure that is at or within a tolerance of the pressures exerted by the motor, the hydraulic pressure system, or other mechanical component to allow for more uniform pressure along the surface of the set of dies 1022, including the particular die 1122 illustrated in FIG. 15. In another implementation, the pressure within the zone 1169 can be at or near ambient pressure. In the same or different implementation, the pressure within the zone 1165 can remain at vacuum pressure, be at or near ambient pressure, or a pressure that is substantially the same as within the zone 1169.

The bonding can be performed at room temperature (for example, at a temperature in a range from 20° C. to 25° C.) or higher. Bonding is performed at a temperature less than a subsequent anneal to expand conductive metal within the dies and at the die bonding sites. The temperature may be limited depending on films present during bonding or components within the die bonding system 100. For example, the temperature may be no higher than approximately 200° C. After reading this specification, skilled artisans will be able to determine the pressure and temperature used for bonding.

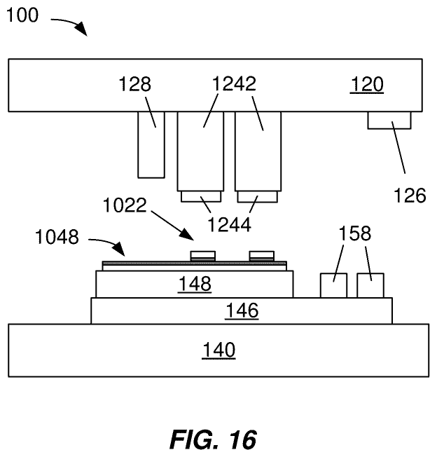

FIG. 16 includes a cross-sectional view of the die bonding system 100 after the set of dies 1022 are bonded to corresponding die bonding sites of the bonding substrate 1048. At this point in the method, one transfer cycle has been completed. In an implementation, for each die within the set of dies 1022, a maximum X-direction alignment error between the center of the die and the center of its corresponding die bonding site is at most 50 microns. In the same or different implementation, for each die within the set of dies 1022, a maximum Y-direction alignment error between the center of the die and the center of its corresponding die bonding site is at most 50 microns. In any of the foregoing or a different implementation, for each die within the set of dies 1022, a maximum θ_{Z} misalignment between the die and its corresponding die bonding site may be at most 3 mrad.

A determination is made whether more dies are to be bonded to the bonding substrate at decision diamond 868 in FIG. 8. If more dies are to be transferred (“YES” branch), the method continues starting at block 822 with a next set of dies transferred during another transfer cycle. The method can be iterated as many times as needed for the bonding substrate 1048 to have a desired number of dies. If no more dies are to be transferred (“NO” branch from decision diamond 868 in FIG. 8), the transfer operation is completed.

A hybrid bonding process can include three steps that include a bonding operation, a first anneal to cause the metal within the dies and at the die bonding sites to expand and contact each other, and an optional second anneal to cause metal atoms to cross the metal-metal interface and reduce contact resistance. The previously described methods correspond to the bonding operation.

After all of the transfer cycles have been performed and the transfer operation is completed, the bonding substrate 1048 and the corresponding bonded dies can be annealed at a temperature in a range from 180° C. to 400° C. In an implementation, annealing may be performed at one or more temperatures. As the temperature of the conductive metal increases, the conductive metal expands. The conductive metal in electrical components within the bonding substrate 1048 contacts the conductive metal in the bonded dies to make a physical and electrical coupling between the conductive materials. If needed or desired, the anneal temperature can be increased further, so that atoms from the conductive metals can cross the interfaces between the electrical components in the bonding substrate 1048 and the bonded dies and reduce contact resistance. In an implementation, the physical and electrical coupling can be a physical and electrical connection. Thus, the bonded dies and the sets of electrical components in the bonding substrate 1048 can allow voltages to be passed and current to flow between the bonded dies and the sets of electrical components. The bonding substrate 1048 can be removed from the die bonding system 100 or moved to a different portion of the die bonding system 100 or a different tool to perform the anneal operations.

The method can further include performing one or more post-bonding operations at block 882 in FIG. 8. Non-limiting examples electrical testing the electronic devices that includes the bonded dies, dicing the bonding substrate into individual electronic devices, cleaning the electronic devices, packaging the electronic devices, or performing another suitable post-bonding operation. The order in which the post-bonding operations may or may not depend on the particular electronic devices. For example, the packaging operation may be performed before or after the dicing operation is performed. Still further, more than one electrical test may be performed at different times where an intervening operation may or may not be performed between the electrical tests. For example, a first electrical test for electrical shorts or electrical opens may be performed before packaging. After packaging, a second electrical test can be performed to test a memory to ensure data can be written and retrieved or a processor to ensure instructions can be performed properly. At this point in the method, electronic devices have been made.

The die bonding system 100 as illustrated in FIGS. 1 to 7 is well suited to adjust the positions of the die chucks 1244 within the array of bonding heads 124 relatively quicker as compared to a conventional die bonding system. With respect to the registration and metrology operation, an adjustment cycle can start from a first point in time when signals from the alignment hardware 158 are processed during the current adjustment cycle at the controller 160 with respect to a current position of the set of dies and ends at a second point in time when adjusting the position of the movable platform 480 is completed. In an implementation, the adjustment cycle can correspond to blocks 964 and 966 in FIG. 9. The die bonding system 100 can perform at a adjustment cycle frequency of at least 50 Hz, at least 200 Hz, at least 500 Hz, or at least 1.1 kHz. In an implementation, the die bonding system 100 may be able to perform at a adjustment cycle frequency of at most 5 kHz.

In the same or different implementation, three, rather than four, alignment actuators can be used to move the movable platform 480 in the X-Y plane. Thus, the number of alignment actuators can be the same or different than the number of bonding actuators. The implementation with three alignment actuators may be able to achieve the previously described adjustment cycle frequencies. The ability to achieve such high adjustment cycle frequencies can allow the throughput of the die bonding system 100 to significantly increase. The inventor has found that this bonding system can achieve at a high bonding rate that provides for high throughput with submicron positioning accuracy. Previous bonding tools have difficulty achieving both submicron accuracy and the high throughput.

The die bonding system as previously described can achieve high precision with respect bonding dies to the bonding substrate and achieve high production throughput. In an implementation, the die bonding system can achieve an X-direction linear travel range is at most +/−0.25% of the length of the movable platform, and a Y-direction linear travel range is at most +/−0.25% of the width of the movable platform. The same or different implementation, the die bonding system can achieve an X-direction linear travel range is at most +/−50 microns, at most +/−100 microns, or at most +/−200 microns, and a Y-direction linear travel range is at most +/−50 microns, at most +/−100 microns, or at most +/−200 microns. In either or both of the previous implementation or a different implementation, the movable platform has a characteristic including a first rotation about a z-axis extending in a Z-direction through a center of mass of the movable platform, and an angular travel range of the first rotation is at most +/−3 mrad, at most +/−6 mrad, at most +/−10 mrad, at most +/−20 mrad, or at most +/−50 mrad. The die bonding system can achieve an adjustment cycle frequency of at least 50 Hz. The die bonding system and method are understood better after reading this specification in conjunction with the figures.

Note that not all of the activities described above in the general description or the examples are required, that a portion of a specific activity may not be required, and that at least one further activities can be performed in addition to those described. Still further, the order in which activities are listed is not necessarily the order in which they are performed.

Benefits, other advantages, and solutions to problems have been described above with regard to specific implementations. However, the benefits, advantages, solutions to problems, and any feature(s) that can cause any benefit, advantage, or solution to occur or become more pronounced are not to be construed as a critical, required, or essential feature of any or all the claims.

The specification and illustrations of the implementations described herein are intended to provide a general understanding of the structure of the various implementations. The specification and illustrations are not intended to serve as an exhaustive and comprehensive description of all of the elements and features of systems and apparatuses that use the structures or methods described herein. Separate implementations can also be provided in combination in a single implementation, and conversely, various features that are, for brevity, described in the context of a single implementation, can also be provided separately or in any subcombination. Further, reference to values stated in ranges includes each and every value within that range. Many other implementations can be apparent to skilled artisans only after reading this specification. Other implementations can be used and derived from the disclosure, such that a structural substitution, logical substitution, or another change can be made without departing from the scope of the disclosure. Accordingly, the disclosure is to be regarded as illustrative rather than restrictive.

What is claimed is:

1. A die bonding system, comprising:
a frame;
a movable platform adapted to retain a die chuck;
a set of bonding actuators operably coupled to the frame and the movable platform; and
a set of alignment actuators operably coupled to the frame and the movable platform,
wherein each bonding actuator is adapted to apply a bonding force to the movable platform in a first direction parallel to and offset from a central axis passing through a center of the movable platform, and
wherein each alignment actuator is adapted to apply an alignment force to the movable platform along an alignment force plane that is orthogonal to the central axis.

2. The die bonding system of claim 1,
wherein the set of bonding actuators is adapted to adjust a position in the first direction, tip, and tilt of the movable platform relative to the frame, and the set of bonding actuators are adapted to supply a peak bonding force to the movable platform.

3. The die bonding system of claim 1, wherein:
the set of alignment actuators is adapted to adjust a position in a second direction, a position in a third direction, and a rotation about the central axis along a plane perpendicular to the central axis of the movable platform relative to the frame, and
the second direction is orthogonal to the first direction, and the third direction is orthogonal to the first direction.

4. The die bonding system of claim 1, wherein the set of bonding actuators is adapted to apply the bonding forces to the movable platform that is at least two times the alignment forces adapted to be applied to the movable platform by the set of alignment actuators.

5. The die bonding system of claim 1, wherein a peak bonding force of each bonding actuator within the set of bonding actuators is at least 110 times a peak alignment force of each alignment actuator within the set of alignment actuators.

6. The die bonding system of claim 1, further comprising the die chuck, wherein the movable platform includes a die chuck retention zone, and a location of the die chuck is adjustable within the die chuck retention zone.

7. The die bonding system of claim 6, wherein:
while the die chuck is retained within the die chuck retention zone, a center of a die holding region of the die chuck is within a polygon, and
vertexes of the polygon are at locations at which the set of bonding actuators apply the bonding forces to the movable platform.

8. The die bonding system of claim 1, further comprising the die chuck, wherein:
the die chuck is adapted to modulate a shape of a die during bonding, and
the set of bonding actuators is adapted to apply the bonding force sufficient to overcome modulation of the shape of the die such that the die complies with a die bonding surface of a substrate.

9. The die bonding system of claim 1, wherein when the movable platform is in a neutral state, each alignment actuator within the set of alignment actuators is adapted to move the movable platform along a plane perpendicular to the central axis, and the plane passes through a center of mass of the movable platform.

10. The die bonding system of claim 1, wherein:
the set of bonding actuators has a first number of actuators,
the set of alignment actuators has a second number of actuators, and
the first number is different from the second number.

11. A die bonding system, comprising:
a frame;
a movable platform adapted to retain a die chuck;
a set of bonding actuators;
a set of bonding flexures, wherein each of the bonding flexures has a corresponding bonding actuator, and each pair of a bonding flexure and its corresponding bonding actuator is operably coupled to the frame and the movable platform;
a set of alignment actuators; and
a set of alignment flexures, wherein each of the alignment flexures has a corresponding alignment actuator, and each pair of an alignment flexure and its corresponding alignment actuator is operably coupled to the frame and the movable platform,
wherein the die bonding system has an adjustment cycle frequency of at least 50 Hz, wherein the adjustment cycle frequency corresponds to a start time when a signal corresponding to a position of the movable platform is processed begins for a current adjustment cycle until an end time when adjusting the movable platform from a prior orientation to a new orientation is completed, wherein adjusting is performed in response to processing the signal during the current adjustment cycle.

12. The die bonding system of claim 11, wherein:
the movable platform has a length in an X-direction, a width in a Y-direction, and a thickness in a Z-direction, wherein the length≥the width>the thickness,
an X-direction linear travel range is at most +/−0.90% of the length of the movable platform, and
a Y-direction linear travel range is at most +/−0.90% of the width of the movable platform.

13. The die bonding system of claim 11, wherein:
the movable platform is adapted to achieve a position within an X-Y plane,
the movable platform has a characteristic including a first rotation about a z-axis extending in a Z-direction through a center of mass of the movable platform, wherein the Z-direction is orthogonal to the X-Y plane, and
an angular travel range of the first rotation is at most +/−50 mrad.

14. The die bonding system of claim 13, wherein the movable platform:
has a length in an X-direction, a width in a Y-direction, and a thickness in the Z-direction, wherein the length ≥the width >the thickness, and
has further characteristics including:
a second rotation about an x-axis extending in the X-direction through the center of mass of the movable platform, and an angular travel range of the second rotation is +/−50 mrad,
a third rotation about a y-axis extending in the Y-direction through the center of mass of the movable platform, an angular travel range of the third rotation is +/−50 mrad, and
in the Z-direction that is orthogonal to the X-Y plane, a Z-direction linear travel range is at most +/−2.5% of the length of the movable platform or at most +/−2.5% of the width of the movable platform.

15. The die bonding system of claim 11, wherein the adjustment cycle frequency is at least Hz.

16. The die bonding system of claim 11, wherein each of the bonding actuators is adapted to provide a force of at least 20 N.

17. A method, comprising:
coupling a first die to a first die chuck of a die bonding system, wherein the die bonding system includes a first bonding head that includes:
a first frame;
the first die chuck;
a first movable platform that retains the first die chuck;
a first set of first bonding actuators operably coupled to the first frame and the first movable platform; and
a first set of first alignment actuators operably coupled to the first frame and the first movable platform,
wherein each first bonding actuator is adapted to apply a first bonding force to the first movable platform in a first direction parallel to and offset from a first central axis passing through a center of the first movable platform, and
wherein each first alignment actuator is adapted to apply a first alignment force to the first movable platform along a first alignment force plane that is orthogonal to the first central axis,
coupling a second die to a second die chuck of the die bonding system, wherein the die bonding system further includes a second bonding head that is spaced apart from the first bonding head and includes:
a second frame;
the second die chuck;
a second movable platform that retains the die second chuck;
a second set of second bonding actuators operably coupled to the second frame and the second movable platform; and
a second set of second alignment actuators operably coupled to the second frame and the second movable platform,
wherein each second bonding actuator is adapted to apply a second bonding force to the second movable platform in a second direction parallel to and offset from a second central axis passing through a center of the second movable platform, and
wherein each second alignment actuator is adapted to apply a second alignment force to the second movable platform along a second alignment force plane that is orthogonal to the second central axis passing;
adjusting the first movable platform to a first adjusted orientation, wherein adjusting the first movable platform is performed using at least one actuator from any one or more actuators within the first set of first bonding actuators and the first set of first alignment actuators;
adjusting the second movable platform to a second adjusted orientation, wherein adjusting the second movable platform is performed using at least one actuator from any one or more actuators within the second set of second bonding actuators and the second set of second alignment actuators;
bonding the first die to a first die bonding site of a substrate, wherein bonding the first die includes activating the first set of first bonding actuators; and
bonding the second die to a second die bonding site of the substrate, wherein bonding the second die includes activating the second set of second bonding actuators,
wherein the first die bonding site is spaced apart from the second die bonding site, and bonding the first die and bonding the second die are performed simultaneously during at least a same point in time.

18. The method of claim 17, further comprising:
obtaining first signals from a first set of first position sensors, wherein the first signals correspond to a first prior orientation of the first movable platform, wherein adjusting the first movable platform is performed before adjusting the first movable platform to the first adjusted orientation; and
obtaining second signals from a second set of second position sensors, wherein the second signals correspond to a second prior orientation of the second movable platform, wherein adjusting the second movable platform is performed before adjusting the second movable platform to the second adjusted orientation,
wherein a first cycle starts at a first point in time when processing the first signals begins and ends at a second point in time when adjusting the first movable platform is completed,
wherein a second cycle starts at a third point in time when processing the second signals begins and ends at a fourth point in time when adjusting the second movable platform is completed, and
wherein each of the first cycle and the second cycle corresponds to a frequency of at least 50 Hz.

19. The method of claim 17, wherein:
a surface of the substrate lies along an X-Y plane and includes the first die bonding site and the second die bonding site,
each of the first die and the first die bonding site has a center,
a maximum X-direction misalignment between the center of the first die and the center of the first die bonding site is at most 50 microns, and
a maximum Y-direction misalignment between the center of the first die and the center of the first die bonding site is at most 50 microns.

20. The method of claim 17, wherein:
the first movable platform has a die chuck retention surface along an X-Y plane,
after adjusting the first movable platform, the first movable platform has characteristics including a first rotation about a z-axis extending in a Z-direction through a center of mass of the first movable platform, wherein the Z-direction is orthogonal to the X-Y plane, a second rotation about an x-axis extending in a first X-direction through the center of mass of the first movable platform, and a third rotation about a y-axis extending in a Y-direction through the center of mass of the first movable platform, and
for each of the first rotation, the second rotation, and the third rotation, an angular travel range is at most +/−50 mrad.
